(19) United States
(12) Patent Application Publication
(10) Pub. No.: US 2009/0250777 A1
(43) Pub. Date: Oct. 8, 2009

(54) IMAGE SENSOR AND IMAGE SENSOR MANUFACTURING METHOD

(75) Inventor: Makoto Takamiya, Tokyo (JP)

Correspondence Address: COWAN LIEBOWITZ & LATMAN P.C.;JOHN J TORRENTE, 1133 AVE OF THE AMERICAS, NEW YORK, NY, 10036, US

(73) Assignee: CANON KABUSHIKI KAISHA, Tokyo (JP)

(21) Appl. No.: 12/413,141

(22) Filed: Mar. 27, 2009

(30) Foreign Application Priority Data
Apr. 4, 2008 (JP) 2008-098746

(51) Int. Cl. H01L 31/0232

(52) U.S. Cl. 257/432; 438/72; 257/E31.127

(57) ABSTRACT

In an upper waveguide structure (14), a width (W1) of the upper portion is larger than a width (W2) of the lower portion. The upper waveguide structure (14) has a side face (14a) which obliquely extends from an edge portion (14b) of the upper face to an edge portion (14c) of the lower face to come close to a normal (PA1) passing through the center of a light receiving surface (2a) of a photoelectric conversion unit (2). A gap (11) in the air gap structure (AG1) is formed by etching a first insulating layer (4a l: see FIG. 4A) serving as a first interlayer dielectric film (4a) so as to expose not an inner region (2a1) but an outer region (2a2) on the light receiving surface (2a) of the photoelectric conversion unit (2).

### BACKGROUND OF THE INVENTION

1. Field of the Invention

The present invention relates to an image sensor and image sensor manufacturing method.

2. Description of the Related Art

Image sensors used in image sensing apparatuses such as a digital still camera are roughly classified into CCD sensors and CMOS sensors.

Japanese Patent Laid-Open No. 2002-141488 discloses a CCD sensor 1000 as shown in FIG. 11. FIG. 11 is a sectional view showing the structure of a main part (one pixel) of the CCD sensor 1000.

In FIG. 11, a semiconductor substrate 1001 is made of, for example, silicon. A photoelectric conversion element 1002 includes a photodiode. An oxide film 1003 is formed on the semiconductor substrate 1001.

Wiring layers 1004 are made of, for example, polysilicon. The wiring layers 1004 transfer predetermined signals. An example of the predetermined signals is a clock signal for transferring charges converted by the photoelectric conversion element 1002.

A light shielding layer 1006 is made of, for example, tungsten. The light shielding layer 1006 is arranged to mainly cover the wiring layers 1004 via an interlayer dielectric film. The light shielding layer 1006 shields a vertical CCD register 1005 for charge transfer from light.

A first passivation film 1007 is made of, for example, SiO₂. The first passivation film 1007 protects the photoelectric conversion element 1002 and the like from outer air (O₂ and H₂O), impurity ions (K⁺ and Na⁺), and the like.

A second passivation film 1008 is made of, for example, an SiON-based material. The second passivation film 1008 also protects the photoelectric conversion element 1002 and the like from outer air (O₂ and H₂O), impurity ions (K⁺ and Na⁺), and the like.

A planarized layer 1009 is made of an organic material. The planarized layer 1009 reduces steps on the upper face of the second passivation film 1008. The planarized layer 1009 planarizes a major surface 1011.

A microlens 1010 focuses light coming from an object on the photoelectric conversion element 1002. The microlens 1010 is arranged on the major surface 1011 of the planarized layer 1009.

The planarized layer 1009 also has a function of adjusting the focal length of the microlens 1010 to focus light on the photoelectric conversion element 1002. The thickness of the planarized layer (transparent photosensitive resin layer) 1009 is determined by the curvature of the lens and the refractive index of the lens material.

Japanese Patent Laid-Open No. 2002-083948 discloses a CMOS sensor 1050 as shown in FIG. 12. FIG. 12 is a sectional view showing the structure of a main part (one pixel) of the CMOS sensor 1050.

In FIG. 12, reference numeral 1051 denotes a silicon substrate (Si substrate). A light receiving portion 1052 serves as a photoelectric conversion element. The light receiving portion 1052 is formed in the silicon substrate 1051. The light receiving portion 1052 is, for example, a photodiode.

A transfer electrode 1053 serves as the gate of a transfer transistor. The transfer transistor transfers photocharges generated in the light receiving portion 1052 to a floating diffusion (FD: not shown). The FD is formed in the silicon substrate 1051.

A light shielding film 1055 functions to cut off light so that light enters only the light receiving portion 1052.

An interlayer dielectric film 1054 is made from, for example, SiO₂. The interlayer dielectric film 1054 is formed to cover the transfer electrode 1053 and light shielding film 1055.

A planarized film 1056 provides a flat upper face 1056a which reduces steps formed on the upper face of the interlayer dielectric film 1054 by a pattern of the transfer electrode 1053 and a wiring layer (not shown).

A color filter 1057 transmits light of a predetermined wavelength. The color filter 1057 transmits light beams of, for example, red, green, and blue wavelengths.

A planarized film 1058 provides a flat upper face 1058a which reduces steps formed on the upper face of the color filter 1057.

A microlens 1059 is formed on the planarized film 1058. The lens shape of the microlens 1059 is determined to focus a light beam entering from a photographing lens (not shown) on the light receiving portion 1052.

The following techniques have been proposed to increase the efficiency at which light refracted by the microlens is directed to the photoelectric conversion element in the image sensor.

According to a technique disclosed in Japanese Patent Laid-Open No. 11-274443, an inner-layer lens is interposed between a microlens and a light-shielding film above a photoelectric conversion element. According to Japanese Patent Laid-Open No. 11-274443, with this structure, light refracted by the microlens is easily directed to the photoelectric conversion element while bypassing the light shielding film, thereby increasing the actual aperture ratio.

According to a technique disclosed in Japanese Patent Laid-Open No. 5-283661, an optical waveguide which is surrounded by a reflecting surface on the side face and formed of a transparent substance is arranged to connect a condenser lens and a light receiving portion. According to Japanese Patent Laid-Open No. 5-283661, with this structure, even light which has been eclipsed in a conventional structure can enter the light receiving portion.

According to a technique disclosed in Japanese Patent Laid-Open No. 2004-193500, a well formed by burying a high-refractive-index layer in a low-refractive-index layer is arranged on a light receiving sensor. According to Japanese Patent Laid-Open No. 2004-193500, incident light can be directed into the light receiving sensor without leaking it.

Recently, the resolution tends to increase by increasing the number of pixels without increasing the image sensor size. The pixel size decreases, and the pixel pitch is coming close to 2 μm or less. The pixel pitch of 2 μm is close to the wavelength region of visible light.

The present inventor thinks that, in this case, to correctly consider the state of light guiding from a photographing lens to a photodiode (photoelectric conversion unit) in each pixel, the state of light guiding cannot be fully examined by geometrical optics, and it needs to be examined by wave optics.

For example, a light beam, which converges on one point in an examination by geometrical optics, does not converge on one point in an examination by wave optics, as represented by FIG. 13A. In the examination by wave optics, the diameter of a light beam which can be converged by focusing light refracted by a circular aperture (photographing lens) is obtained as represented by FIG. 13B. More specifically, a radius rc at a position where the light quantity in a profile representing the diffraction pattern intensity distribution (Airy disk pattern) of the circular aperture becomes 0 is

rc=1.22*λ*(F-number)=0.61*λ/NA (1)

where the F-number=(1/2)*NA, and NA=n*sin α. From equation (1), the diameter of a light beam which can be converged can be given by

d=2*rc=1.22*λ/NA (2)

In this case, even if light is tried to focus on one point on the light receiving surface of a photodiode by arranging a microlens and inner-layer lens between the photographing lens and the photodiode, as described in Japanese Patent Laid-Open No. 11-274443, no light can be focused on one point owing to the above-described reason.

For example, when the diameter of the circular aperture (photographing lens) is 1.5 μm, the distance between the principal plane of the photographing lens and its convergence point is 3 μm, and the refractive index of the light guide is 1.6, the NA becomes about 0.4. When the wavelength of incident light is 0.55 nm, the diameter of a light beam which can be converged is calculated in accordance with equation (2):

d=1.68 μm (3)

This value is close to the above-mentioned pixel pitch, and close to the dimension of an opening region defined by the light shielding layer on the photodiode.

For this reason, light refracted by the microlens is often reflected by the light shielding layer (Al or Cu) of each pixel before reaching the light receiving surface of the photodiode.

The present inventor thinks that this problem can be suppressed by forming an optical waveguide described in Japanese Patent Laid-Open No. 5-283661 or a well described in Japanese Patent Laid-Open No. 2004-193500 between the microlens and the photodiode. The present inventor also thinks that, even if the pixel size decreases, the efficiency at which light refracted by the microlens is directed to the photodiode (photoelectric conversion unit) can be increased.

However, both the optical waveguide described in Japanese Patent Laid-Open No. 5-283661 and the well described in Japanese Patent Laid-Open No. 2004-193500 are formed by burying a substance higher in refractive index than an insulating film in an opening formed by etching the insulating film on a light receiving surface so as to expose the entire light receiving surface of the photodiode. The present inventor thinks that this etching damages the entire light receiving surface of the photodiode, and noise generated in the photodiode may increase.

### SUMMARY OF THE INVENTION

It is an aim of the present invention to provide a new structure for increasing the efficiency at which light having passed through a microlens is directed to a photoelectric conversion unit when the pixel size decreases.

According to the first aspect of the present invention, there is provided an image sensor comprising: a photoelectric conversion unit; and an optical waveguide which directs light to the photoelectric conversion unit, the optical waveguide including an upper waveguide structure in which a substance higher in refractive index than a first insulating portion is surrounded on a side face by the first insulating portion so as to make the light travel toward the photoelectric conversion unit, and a gap structure in which a member is arranged between the photoelectric conversion unit and the upper waveguide structure, and a gap is formed between the member and a second insulating portion.

According to the second aspect of the present invention, there is provided an image sensor comprising: a photoelectric conversion unit; and an optical waveguide which directs light to the photoelectric conversion unit, the optical waveguide including an upper waveguide structure in which a substance higher in refractive index than a first insulating portion is surrounded on a side face by the first insulating portion so as to make the light travel toward the photoelectric conversion unit, and a gap structure which is obtained by etching an insulating layer to be arranged between the photoelectric conversion unit and the upper waveguide structure so as to expose not an inner region but an outer region on a light receiving surface of the photoelectric conversion unit, and in which a gap is formed between a member serving as a portion on the inner region in the insulating layer and a second insulating portion serving as a peripheral portion on the periphery of the outer region in the insulating layer.

According to the third aspect of the present invention, there is provided a method of manufacturing an image sensor having a photoelectric conversion unit, the method including: a first step of forming a first insulating layer so as to cover the photoelectric conversion unit; a second step of etching the first insulating layer so as to expose not the inner region but the outer region on a light receiving surface of the photoelectric conversion unit and thereby forming a gap structure in which a gap is formed between a member serving as a portion on the inner region in the first insulating layer, and a first insulating film serving as a peripheral portion on the periphery of the outer region in the first insulating layer; a third step of forming an antireflection film on the gap structure; a fourth step of forming a second insulating layer on the antireflection film; a fifth step of forming an opening in the second insulating layer at a position above the gap structure and thereby forming a second insulating film; a sixth step of burying a substance higher in refractive index than the second insulating film in the opening and thereby forming an upper waveguide structure; and a seventh step of forming a microlens above the upper waveguide structure, wherein the upper waveguide structure, the antireflection film, and the gap structure function as an optical waveguide which directs light having passed through the microlens to the photoelectric conversion unit.

The present invention can provide a new structure for increasing the efficiency at which light having passed through a microlens is directed to a photoelectric conversion unit when the pixel size decreases.

Further features of the present invention will become apparent from the following description of exemplary embodiments with reference to the attached drawings.

### BRIEF DESCRIPTION OF THE DRAWINGS

FIG. 1 is a plan view showing the schematic arrangement of an image sensor 100 according to the first embodiment of the present invention;

FIG. 2 is a sectional view showing the sectional structure of a pixel P in the image sensor 100 according to the first embodiment of the present invention;

FIG. 3 is a plan view when viewed from an arrow A-A′ in FIG. 2;

FIGS. 4A to 4H are sectional views showing steps in a method of manufacturing the image sensor 100 according to the first embodiment of the present invention;

FIGS. 5A to 5C are sectional views showing the section model shapes of pixels in image sensors according to comparative examples (FIG. 5A: microlens, FIG. 5B: inner-layer lens) and the first embodiment (FIG. 5C);

FIG. 6 is a graph showing the incident angle dependences of the light receiving efficiency of a photoelectric conversion unit 2 according to the comparative examples (“microlens” and “inner-layer lens”) and the first embodiment;

FIG. 7 is a graph showing the F-number dependences of the light receiving efficiency of the photoelectric conversion unit 2 according to the comparative examples (“microlens” and “inner-layer lens”) and the first embodiment;

FIGS. 8A and 8B are sectional views showing the sectional structure of an image sensor 200 according to the second embodiment of the present invention;

FIG. 9 is a sectional view showing the sectional structure of an image sensor 300 according to the third embodiment of the present invention;

FIG. 10 is a sectional view showing the sectional structure of an image sensor 400 according to the fourth embodiment of the present invention;

FIG. 11 is a sectional view for explaining a conventional technique;

FIG. 12 is a sectional view for explaining a conventional technique; and

FIGS. 13A and 13B are views for explaining a problem to be solved by the present invention.

### DESCRIPTION OF THE EMBODIMENTS

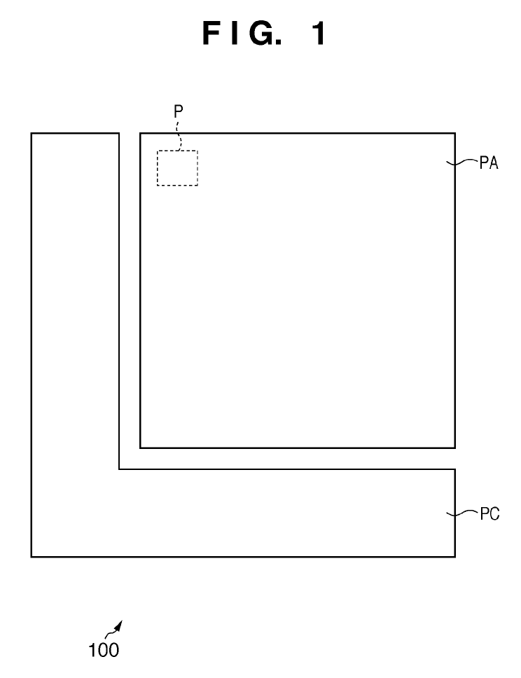

The schematic arrangement of an image sensor 100 according to the first embodiment of the present invention will be explained with reference to FIG. 1. FIG. 1 is a plan view showing the schematic arrangement of the image sensor 100 according to the first embodiment of the present invention.

The image sensor 100 includes a pixel array PA and peripheral circuit PC. In the pixel array PA, a plurality of pixels P are arrayed in the row and column directions. The peripheral circuit PC is arranged on the periphery of the pixel array PA.

A case wherein the image sensor 100 is a CMOS sensor will be explained. The peripheral circuit PC includes a vertical scanning circuit which drives each pixel P, a readout circuit which reads out a signal from each pixel P and holds it, an output circuit, and a vertical scanning circuit which transfers a signal held in the readout circuit to the output circuit.

Each pixel P includes a photoelectric conversion unit, transfer unit, charge-voltage converter, reset unit, and output unit. The photoelectric conversion unit generates charges corresponding to light, and accumulates the generated charges as a signal. The transfer unit transfers charges generated in the photoelectric conversion unit to the charge-voltage converter. The transfer unit is, for example, a transfer MOS transistor. Upon receiving, at the gate (transfer electrode), an active-level transfer signal from the vertical scanning circuit, the transfer unit is turned on to perform a transfer operation. The charge-voltage converter converts transferred charges into a voltage. The charge-voltage converter is, for example, a floating diffusion (FD). The reset unit resets the charge-voltage converter. The reset unit is, for example, a reset MOS transistor. Upon receiving, at the gate, an active-level reset signal from the vertical scanning circuit, the reset unit is turned on to perform a reset operation. The output unit outputs a signal corresponding to the voltage of the charge-voltage converter to a signal line. The output unit is, for example, an amplification MOS transistor. The output unit receives the voltage of the charge-voltage converter at the gate, and outputs a signal corresponding to the voltage from the source to the signal line.

In a case where the image sensor 100 is a CCD sensor, it is different from the case where the image sensor 100 is a CMOS sensor in that not each pixel P but the peripheral circuit PC includes the transfer unit, charge-voltage converter, reset unit, and output unit. In this case, the transfer unit includes, for example, a vertical transfer CCD and horizontal transfer CCD, and performs a transfer operation in accordance with the phase of a transfer signal supplied to each transfer electrode.

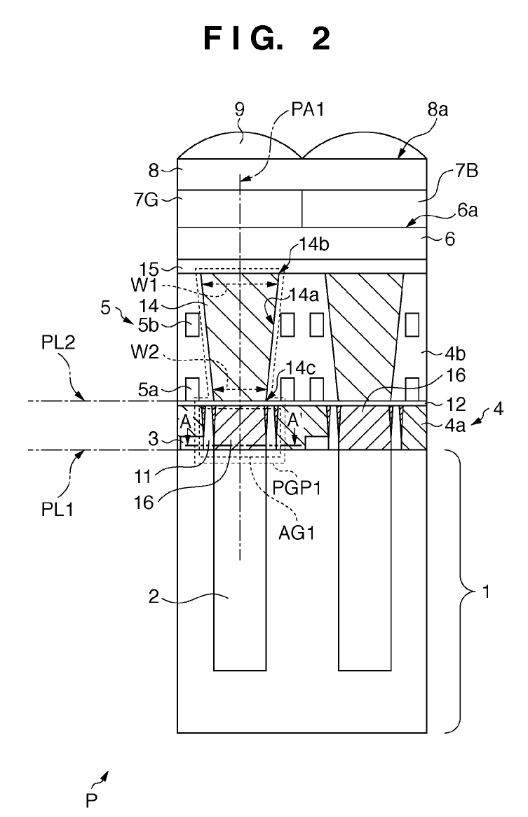

The sectional structure of each pixel P will be explained with reference to FIG. 2. FIG. 2 is a sectional view showing the sectional structure of the pixel P in the image sensor 100 according to the first embodiment of the present invention.

The image sensor 100 includes a photoelectric conversion unit 2, a microlens 9, a plurality of wiring layers 5, a transfer electrode 3, an insulating portion 4, an optical waveguide PGP1, a passivation film 15, a planarized film 6, color filters 7G and 7B, and a planarized film 8.

The photoelectric conversion unit 2 is formed as an impurity region in a semiconductor substrate 1. The semiconductor substrate 1 is made of, for example, silicon (Si). The photoelectric conversion unit 2 generates charges corresponding to light, and accumulates the generated charges as a signal. A plane PL1 includes a light receiving surface 2a (see FIG. 3) of the photoelectric conversion unit 2. The photoelectric conversion unit 2 is, for example, a photodiode.

The microlens 9 is arranged above the photoelectric conversion unit 2. The microlens 9 refracts incident light and directs it to the color filters 7G or 7B. The shape of the microlens 9 is determined such that a light beam entering from a photographing lens (not shown) can be focused on the light receiving surface 2a of the photoelectric conversion unit 2 together with an upper waveguide structure 14 and air gap structure AG1 (both of which will be described later).

Each of the wiring layers 5 transfers the voltage of the above-mentioned charge-voltage converter to the output unit, or functions as a signal line to transfer a signal output from the output unit. The plurality of wiring layers 5 are made of a material which contains an aluminum or a copper as a major component. The plurality of wiring layers 5 include a first wiring layer (lowermost wiring layer) 5a and a second wiring layer 5b. A plane PL2 includes the lower face of the lowermost wiring layer 5a among the plurality of wiring layers 5.

The transfer electrode 3 is an electrode (gate) which receives a signal for causing the transfer unit (transfer MOS transistor) to perform a transfer operation. The transfer electrode 3 is made of, for example, polysilicon.

The insulating portion 4 is arranged adjacent to the side of the optical waveguide PGP1 (to be described later) between the photoelectric conversion unit 2 and the microlens 9. The insulating portion 4 includes a first interlayer dielectric film (second insulating portion and first insulating film) 4a and a second interlayer dielectric film (first insulating portion and second insulating film) 4b. The first interlayer dielectric film 4a is arranged between the photoelectric conversion unit 2 and the lowermost wiring layer 5a, and suppresses electrical leakage between the photoelectric conversion unit 2 and the plurality of wiring layers 5. The first interlayer dielectric film 4a is made of, for example, SiO₂. The second interlayer dielectric film 4b insulates the wiring layers 5 from each other.

The first interlayer dielectric film 4a may also employ a low-permittivity material (low-k material) in order to minimize the thickness while maintaining the insulation property.

The optical waveguide PGP1 is arranged between the photoelectric conversion unit 2 and the microlens 9. The optical waveguide PGP1 directs light having passed through the microlens 9 to the photoelectric conversion unit 2. The optical waveguide PGP1 includes the upper waveguide structure 14, the air gap structure AG1, and an antireflection film 12.

The upper waveguide structure 14 is arranged to receive light having passed through the microlens 9. In the upper waveguide structure 14, a substance higher in refractive index than the second interlayer dielectric film 4b is surrounded on a side face 14a by the second interlayer dielectric film 4b. The high-refractive-index substance is, for example, HDP-SiN (High Density Plasma SiN).

In the upper waveguide structure 14, a width W1 of the upper portion is larger than a width W2 of the lower portion. The upper waveguide structure 14 has the side face 14a which obliquely extends from an edge portion 14b of the upper face to an edge portion 14c of the lower face to come close to a normal PA1 passing through the center of the light receiving surface 2a of the photoelectric conversion unit 2. With this structure, the upper waveguide structure 14 can efficiently receive light. In addition, light which enters the upper waveguide structure 14 and is reflected by the side face 14a can easily travel toward the air gap structure AG1. That is, the upper waveguide structure 14 can increase the efficiency at which light having passed through the microlens 9 is directed to the photoelectric conversion unit 2.

The air gap structure AG1 is arranged between the photoelectric conversion unit 2 and the upper waveguide structure 14 (to be described later), and between the first plane PL1 including the light receiving surface 2a of the photoelectric conversion unit 2 and the second plane PL2 including the lower face of the lowermost wiring layer 5a among the plurality of wiring layers 5. That is, the air gap structure AG1 is positioned close not to the lowermost wiring layer 5a among the plurality of wiring layers 5, but to the surface of the semiconductor substrate 1.

In the air gap structure AG1, a member 16 is arranged on an inner region 2a1 (see FIG. 3) of the light receiving surface 2a between the photoelectric conversion unit 2 and the upper waveguide structure 14. A gap 11 is formed between the member 16 and the first interlayer dielectric film 4a. The member 16 is made of the same substance as that of the first interlayer dielectric film 4a. The gap 11 is filled with a predetermined gas (e.g., inert gas or air), or is in an almost vacuum. The refractive index of the member 16 is higher than that of the gap 11, increasing the efficiency at which light having passed through the microlens 9 is directed to the photoelectric conversion unit 2.

The antireflection film 12 is arranged between the upper waveguide structure 14 and the air gap structure AG1. The antireflection film 12 prevents reflection of light at the interface between the upper waveguide structure 14 (SiN) and the member 16 (SiO₂) in the air gap structure AG1. With the antireflection film 12, light having passed through the microlens 9 and traveling through the upper waveguide structure 14 can easily enter the member 16. That is, the antireflection film 12 can increase the efficiency at which light having passed through the microlens 9 is directed to the photoelectric conversion unit 2.

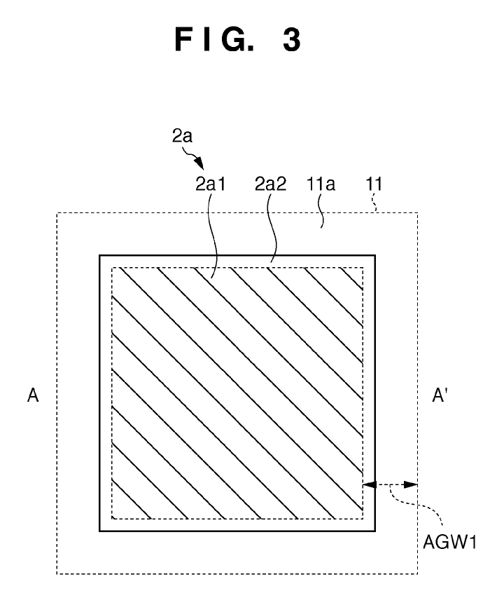

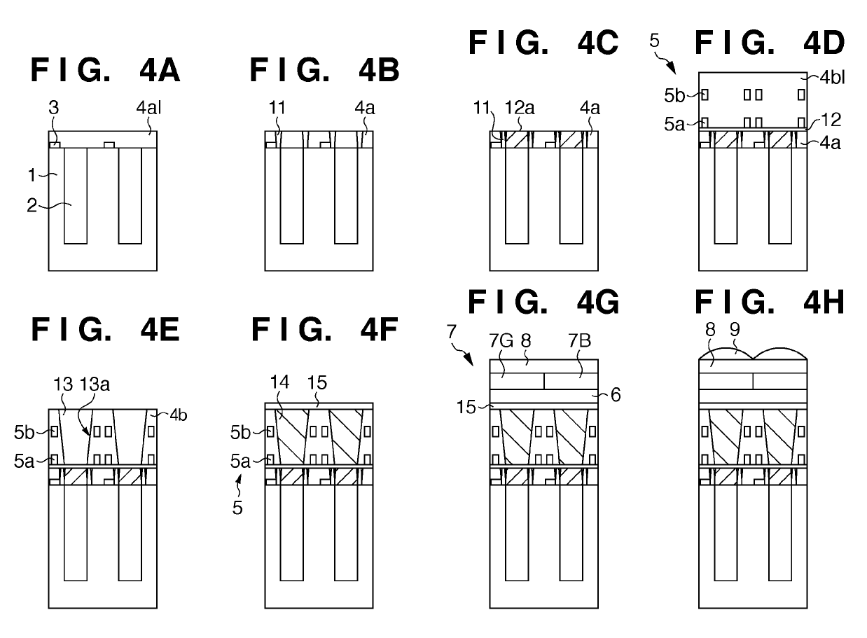

The gap 11 in the air gap structure AG1 can be formed by etching a first interlayer dielectric layer 4a1 (see FIG. 4A) to be formed into the first interlayer dielectric film 4a so as to expose not the inner region 2a1 but an outer region 2a2 on the light receiving surface 2a of the photoelectric conversion unit 2. Etching damage to the light receiving surface 2a of the photoelectric conversion unit 2 when forming the air gap structure AG1 can be reduced, compared to etching the first interlayer dielectric layer 4a1 so as to expose the entire light receiving surface 2a.

The passivation film 15 is arranged on the insulating portion 4 and optical waveguide PGP1. The passivation film 15 protects the photoelectric conversion unit 2 from outer air (O₂ and H₂O), impurity ions (K⁺ and Na⁺), and the like. The passivation film 15 is made of, for example, SiN.

The planarized film 6 is arranged on the passivation film 15. The planarized film 6 reduces steps on the upper face of the passivation film 15 and provides a flat upper face 6a. The planarized film 6 reduces fluctuations in the characteristics of the color filters 7G and 7B arranged on the upper face 6a of the planarized film 6.

The color filters 7G and 7B are arranged on the upper face 6a of the planarized film 6. The color filters 7G and 7B transmit light of a predetermined wavelength (e.g., red, green, and blue wavelengths) out of incident light.

The planarized film 8 is arranged on the color filters 7G and 7B. The planarized film 8 reduces steps on the upper faces of the color filters 7G and 7B and provides a flat upper face 8a. The planarized film 8 reduces fluctuations in the characteristics of the microlenses 9 arranged on the upper face 8a of the planarized film 8.

A method of manufacturing the image sensor 100 according to the first embodiment of the present invention will be explained with reference to FIGS. 4A to 4H. FIGS. 4A to 4H are sectional views showing steps in a method of manufacturing the image sensor 100 according to the first embodiment of the present invention.

In step of FIG. 4A (first step), a transfer electrode 3 is formed on a semiconductor substrate 1 in which a photoelectric conversion unit 2 is formed. The transfer electrode 3 is made of, for example, Poly-Si. A first interlayer dielectric layer (first insulating layer) 4a1 to be formed into the first interlayer dielectric film 4a is formed to cover the photoelectric conversion unit 2 and transfer electrode 3. The first interlayer dielectric layer 4a1 is made of, for example, SiO₂.

In step of FIG. 4B (second step), a through-hole plug (not shown) is formed. Then, the first interlayer dielectric layer 4a1 is etched to expose not the inner region 2a1 (see FIG. 3) but the outer region 2a2 on the light receiving surface 2a of the photoelectric conversion unit 2. As a result, a first interlayer dielectric film 4a and air gap structure AG1 are formed. More specifically, as shown in FIG. 3, a gap 11 having an average width AGW1 of, for example, 0.2 μm is formed on the outer region 2a2 on the light receiving surface 2a of the photoelectric conversion unit 2 and a peripheral region 11a around the light receiving surface 2a. Accordingly, an air gap structure AG1 is formed, in which a member 16 made of the same substance as that of the first interlayer dielectric film 4a is arranged on the inner region 2a1 of the light receiving surface 2a so as to form the gap 11 between the member 16 and the first interlayer dielectric film 4a.

At this time, the gap 11 is formed by almost the same process as a process of forming a through-hole. The section of the gap 11 has a shape slightly tapered downward, and the central axis of this shape is almost vertical.

In step of FIG. 4C (third step), an SiN film 12a serving as part of the antireflection film 12 is formed on the air gap structure AG1 to seal the air gap structure AG1. The SiN film 12a is formed to have a thickness of, for example, 10 nm.

In step of FIG. 4D (third and fourth steps), an SiO₂ film serving as another part of the antireflection film 12 is formed on the SiN film 12a. The SiO₂ film is formed to have a thickness of, for example, 25 nm. An SiN film serving as still another part of the antireflection film 12 is formed on the SiO₂ film. The SiO₂ film is formed to have a thickness of, for example, 15 nm. As a result, an antireflection film 12 is formed from three, SiN (10 nm), SiO₂ (25 nm), and SiN (15 nm) layers from the bottom. After that, a second interlayer dielectric layer 4b1 to be formed into the second interlayer dielectric film 4b, and a plurality of wiring layers 5 including wiring layers 5a and 5b are formed on/above the antireflection film 12. A through-hole plug (not shown) is also formed.

In step of FIG. 4E (fifth step), the second interlayer dielectric layer 4b1 is etched by photolithography to form an opening 13 in the second interlayer dielectric layer (second insulating layer) 4b1 at a position above the air gap structure AG1, thereby forming a second insulating film 4b.

Etching conditions can be controlled to set the inclination angle of a side face 13a of the opening 13 to, for example, 8° with respect to the normal PA1 (see FIG. 2) passing through the center of the light receiving surface 2a. The antireflection film 12 functions as an etching stopper which prevents over-etching of the member 16 when forming an opening 13 having a high aspect ratio (depth/(upper face width)). Hence, etching for forming the opening 13 at high processing accuracy can be executed.

In step of FIG. 4F (sixth step), a substance higher in refractive index than the second interlayer dielectric film 4b is buried in the opening 13 by high-density plasma CVD, forming an upper waveguide structure 14. The substance of the upper waveguide structure 14 is made of, for example, HDP-SiN (High Density Plasma SiN). Then, a passivation film 15 is formed on the upper waveguide structure 14 and second interlayer dielectric film 4b. The passivation film 15 is made of, for example, SiN.

The refractive index of the substance (HDP-SiN) of the upper waveguide structure 14 is about 1.9, which is slightly different from a refractive index “2” of the passivation film 15 (SiN) owing to the conditions of high-density plasma CVD.

When the aspect ratio (depth/(upper face width)) of the opening 13 is, for example, less than 1.8, the substance of the upper waveguide structure 14 (HDP-SiN) can be completely buried in the opening 13. If the aspect ratio of the opening 13 becomes equal to or higher than 1.8, a void is generated in the substance of the upper waveguide structure 14, greatly degrading the optical waveguide function. For this reason, the opening 13 is formed to have the aspect ratio of 1.8 or less as long as the opening 13 does not interfere with the plurality of wiring layers 5.

In step of FIG. 4G, an organic material is spin-coated onto the passivation film 15, forming a planarized film 6. Color filters 7 including color filters 7G and 7B are formed on the planarized film 6 by photolithography. An organic material is spin-coated onto the color filters 7, forming a planarized film 8.

In step of FIG. 4H (seventh step), a microlens 9 is formed on the planarized film 8 above the upper waveguide structure 14. For example, a film made of an organic material or the like is patterned on the planarized film 8, and the pattern is thermally fused to form a microlens 9 having a sphere.

As described above, according to the first embodiment, not the insulating film on the inner region 2a1 but that on the outer region 2a2 on the light receiving surface of the photoelectric conversion unit is etched, reducing etching damage to the light receiving surface of the photoelectric conversion unit. When the pixel size in the image sensor decreases, the efficiency at which light refracted by the microlens is directed to the photoelectric conversion unit can be increased, and noise in the photoelectric conversion unit can be suppressed. The first embodiment can provide a new structure for increasing the efficiency at which light having passed through the microlens is directed to the photoelectric conversion unit when the pixel size decreases.

The results of comparing the first embodiment and comparative examples will be explained.

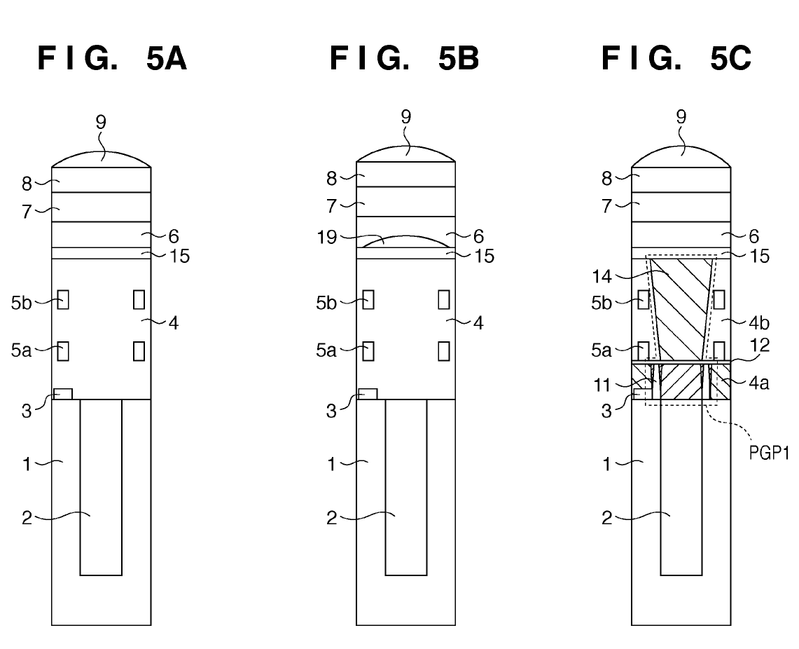

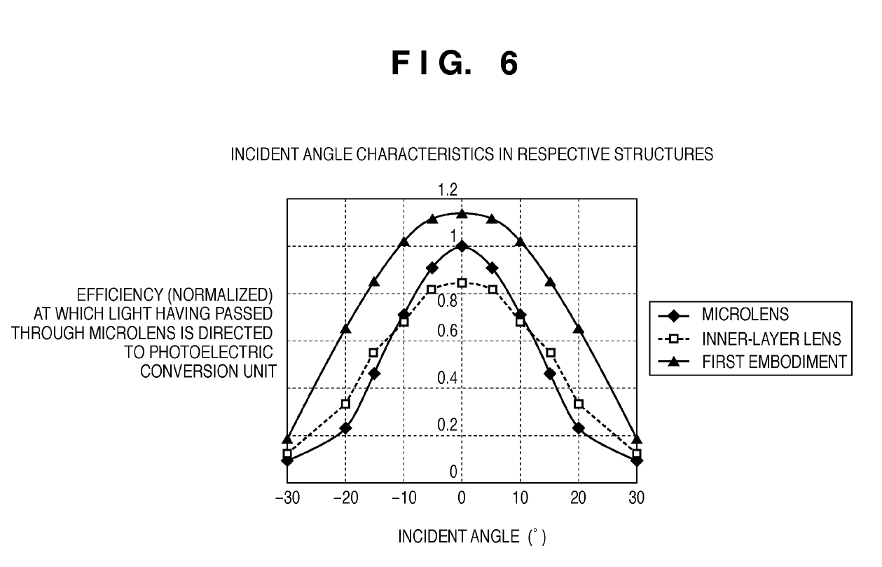

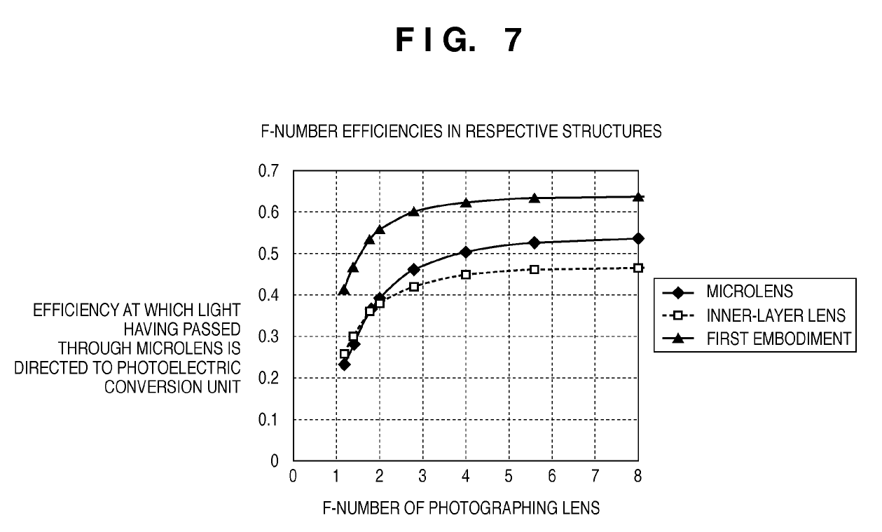

In order to clarify the effects of the first embodiment, a wave simulation was done on the assumption that the pixel pitch was 1.5 μm. More specifically, the incident angle dependence (see FIG. 6) of the light receiving efficiency of the photoelectric conversion unit 2, and the F-number dependence (see FIG. 7) of the light receiving efficiency of the photoelectric conversion unit 2 were obtained for shapes in FIGS. 5A to 5C. FIGS. 5A to 5C are sectional views showing the section model shapes of pixels in image sensors according to comparative examples (FIG. 5A: microlens, FIG. 5B: inner-layer lens) and the first embodiment (FIG. 5C).

FIG. 5A represents a structure in which neither the optical waveguide PGP1 nor an inner-layer lens 19 is arranged between the microlens 9 and the photoelectric conversion unit 2, and light having passed through the microlens 9 is directly directed to the photoelectric conversion unit 2. The structure in FIG. 5A will be called the structure of the comparative example “microlens”.

In the structure of the comparative example “microlens”, the simulated results indicate that it is difficult to converge light beam at one point even at an incident angle of 0°, which is greatly diverged from the result in geometrical optics, as described above. When the incident angle is changed, light is cut off by a plurality of wiring layers 5 (Al or the like) arranged between the microlens and the light receiving surface 2a.

FIG. 5B represents a structure in which the inner-layer lens 19 is arranged between the microlens 9 and the photoelectric conversion unit 2, and light having passed through the microlens 9 and inner-layer lens 19 is directed to the photoelectric conversion unit 2. The structure in FIG. 5B will be called the structure of the comparative example “inner-layer lens”.

In the structure of the comparative example “inner-layer lens”, the simulated results indicate that it is difficult to converge light beam at one point even at an incident angle of 0°, which is greatly diverged from the result in geometrical optics. When the pixel pitch is large, a light beam can be converged more on the light receiving surface 2a by the structure of the comparative example “inner-layer lens” than by the structure of the comparative example “microlens”. However, when the pixel pitch is small, a light beam converges before the light receiving surface 2a owing to the presence of the inner-layer lens 19, decreasing the light receiving efficiency at the incident angle of 0°.

FIG. 5C represents a structure in which the optical waveguide PGP1 is arranged between the microlens 9 and the photoelectric conversion unit 2, and light having passed through the microlens 9 is directed to the photoelectric conversion unit 2 via the optical waveguide PGP1. The structure in FIG. 5C will be called the structure of the first embodiment.

In the structure of the first embodiment, the simulated results indicate that a light beam having passed through the microlens 9 can be directed downward within the upper waveguide structure 14 because of total reflection by the side face of the upper waveguide structure 14. Then, the light beam can be efficiently directed to the light receiving surface 2a via the optical waveguide structure of the air gap structure AG1. At this time, even when the refractive index of the gap 11 in the air gap structure AG1 is 1 and that of the member (SiO₂) 16 is 1.46, if the width of the gap 11 is smaller than the wavelength of light, the actual refractive index of the gap 11 takes not 1 but the average refractive index value. The width of the gap 11 can be as small as possible. However, total reflection condition can be difficult to satisfy unless the gap 11 is wide to some extent. Hence, the widths of the member 16 and gap 11 need to be balanced to implement an efficient waveguide structure. The simulation result reveals that the width of the gap 11 is desirably about 0.2 μm or more.

FIG. 6 is a graph showing the incident angle dependences of the light receiving efficiency of the photoelectric conversion unit 2 according to the comparative examples (“microlens” and “inner-layer lens”) and the first embodiment. The light receiving efficiency is an efficiency at which light having passed through the microlens is directed to the photoelectric conversion unit. In FIG. 6, the ordinate axis represents a light receiving efficiency normalized on the premise that the light receiving efficiency at an incident angle of 0° in the structure of the comparative example “microlens” is 1. The abscissa axis represents the incident angle of light entering the microlens 9.

FIG. 6 shows that a light receiving efficiency in the first embodiment at an incident angle of 0° is higher by about 15% than that in the comparative example “microlens” at an incident angle of 0°. FIG. 6 also shows that a light receiving efficiency in the first embodiment at an incident angle of 0° is higher by about 35% than that in the comparative example “inner-layer lens” at an incident angle of 0°.

Further, light receiving efficiencies in the first embodiment at oblique incident angles of −30° to 0° and 0° to +30° are higher than those in the comparative example “microlens” at oblique incident angles of −30° to 0° and 0° to +30°. Light receiving efficiencies in the first embodiment at oblique incident angles of −30° to 0° and 0° to +30° are higher than those in the comparative example “inner-layer lens” at oblique incident angles of −30° to 0° and 0° to +30°.

FIG. 7 is a graph showing the F-number dependences of the light receiving efficiency of the photoelectric conversion unit 2 according to the comparative examples (“microlens” and “inner-layer lens”) and the first embodiment. The light receiving efficiency is an efficiency at which light having passed through the microlens is directed to the photoelectric conversion unit. In FIG. 7, the ordinate axis represents the light receiving efficiency, and the abscissa axis represents the F-number of the photographing lens.

As shown in FIG. 7, as the F-number of the photographing lens decreases (the lens brightness increases), the exposure time of the photoelectric conversion unit can be shortened. However, light of a large incident angle enters the microlens, decreasing the light receiving efficiency of the photoelectric conversion unit. FIG. 7 shows a decrease in the light receiving efficiency of the photoelectric conversion unit along with a decrease in the F-number. The light receiving efficiency of the photoelectric conversion unit is ideally 1 (efficiency is 100%) for all F-numbers. In practice, as the F-number decreases (the lens brightness increases), the light receiving efficiency of the photoelectric conversion unit decreases.

FIG. 7 shows that light receiving efficiencies in the first embodiment at F-numbers of 1 to 8 are higher than those in the comparative example “microlens” at F-numbers of 1 to 8. A decrease in light receiving efficiency in the first embodiment when the F-number decreases from 8 to 1 is smaller than that in the comparative example “microlens” when the F-number decreases from 8 to 1.

FIG. 7 also shows that light receiving efficiencies in the first embodiment at F-numbers of 1 to 8 are higher than those in the comparative example “inner-layer lens” at F-numbers of 1 to 8.

For example, a light receiving efficiency in the first embodiment at an F-number of 2.8 is about 0.6, which is larger than a light receiving efficiency of about 0.45 in the comparative example “inner-layer lens” at an F-number of 2.8.

A decrease in light receiving efficiency in the first embodiment when the F-number decreases from 8 to 1 is equivalent to that in the comparative example “microlens” when the F-number decreases from 8 to 1.

As shown in FIGS. 6 and 7, the first embodiment can ensure a larger light quantity than that in a conventional structure even in photographing for a short exposure time or photographing in a dark environment by an image sensor having a small pixel pitch. Hence, image data at high S/N ratio can be acquired.

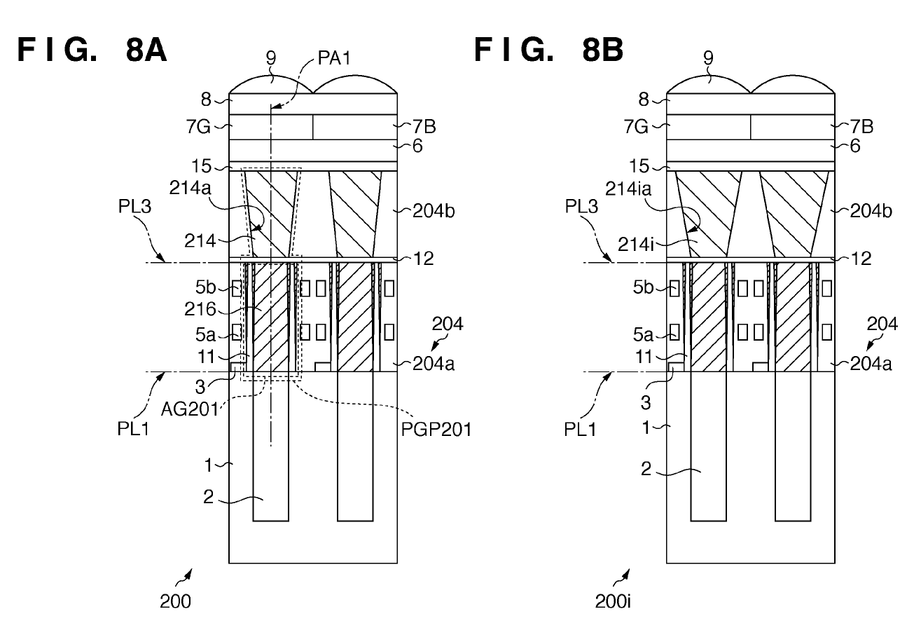

The sectional structure of an image sensor 200 according to the second embodiment of the present invention will be explained with reference to FIGS. 8A and 8B. FIGS. 8A and 8B are sectional views showing the sectional structures of the image sensor 200 according to the second embodiment of the present invention. A difference from the first embodiment will be mainly explained, and a description of the same part will not be repeated.

The image sensor 200 includes an insulating portion 204 and optical waveguide PGP201, instead of the insulating portion 4 and optical waveguide PGP1.

The insulating portion 204 includes a first interlayer dielectric film (second insulating portion and first insulating film) 204a and a second interlayer dielectric film (first insulating portion and second insulating film) 204b. The first interlayer dielectric film 204a is arranged between a third plane PL3 and a first plane PL1. The third plane PL3 is a plane between an uppermost wiring layer 5b among a plurality of wiring layers 5 and a passivation film 15. The third plane PL3 is parallel to the first plane PL1. The second interlayer dielectric film 204b is arranged above the uppermost wiring layer 5b and between the passivation film 15 and the third plane PL3. The ratio of the thickness of the second interlayer dielectric film 204b to that of the first interlayer dielectric film 204a is lower than the ratio in the first embodiment.

The optical waveguide PGP201 includes an upper waveguide structure 214 (FIG. 8A) or 214i (FIG. 8B) and an air gap structure AG201, instead of the upper waveguide structure 14 and air gap structure AG1. The upper waveguide structure 214 or 214i is arranged above the uppermost wiring layer 5b between the passivation film 15 and the third plane PL3. The air gap structure AG201 is arranged between the third plane PL3 and the first plane PL1.

In this case, a member 216 in the air gap structure AG201 becomes narrow in order to avoid interference with the wiring layer 5. The lower portion of the upper waveguide structure 214 or 214i also becomes narrow. However, the upper waveguide structure 214 or 214i does not interfere with any member such as a wiring layer, and can be designed more freely than in a case wherein it interferes with a wiring layer.

For example, as represented by FIG. 8A, the inclination angle of a side face 214a of the upper waveguide structure 214 with respect to a normal PA1 passing through the center of a light receiving surface 2a is set (to, e.g., 8°) equal to the inclination angle in the first embodiment. In this case, the upper face becomes small, but the total reflection condition can be easily satisfied because the inclination of the side face is small.

For example, as represented by FIG. 8B, the inclination angle of a side face 214ia of the upper waveguide structure 214i with respect to the normal PA1 passing through the center of the light receiving surface 2a is set (to, e.g., 12°) larger than the inclination angle in the first embodiment. In this case, the ratio of totally reflected light decreases because the inclination is large, but the upper face becomes large, receiving a large quantity of light from the upper face.

An optimum shape balance can be determined in a trade-off between a decrease in the ratio of totally reflected light and an increase in light which can be received from the upper face.

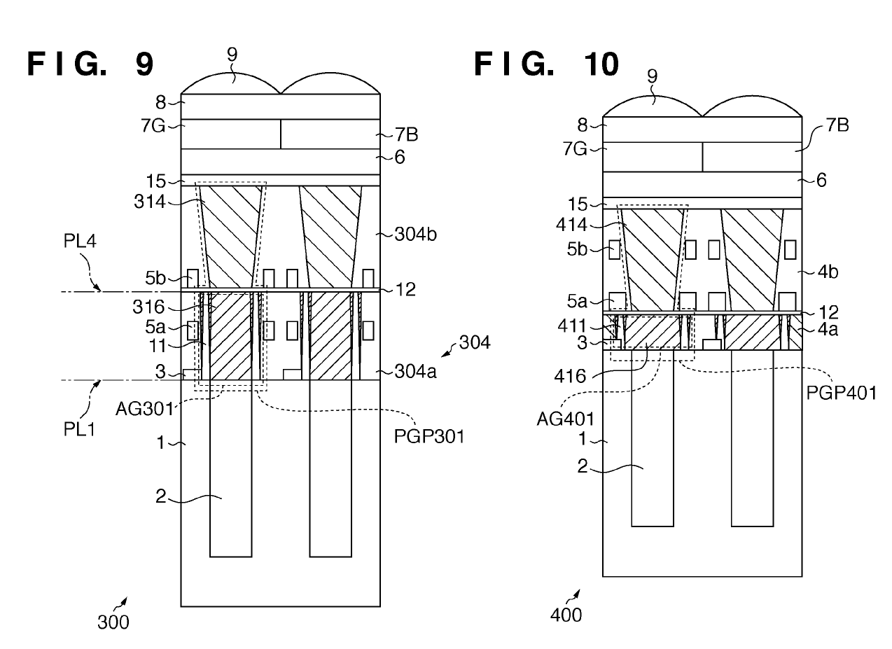

The sectional structure of an image sensor 300 according to the third embodiment of the present invention will be explained with reference to FIG. 9. FIG. 9 is a sectional view showing the sectional structure of the image sensor 300 according to the third embodiment of the present invention. A difference from the first embodiment will be mainly explained, and a description of the same part will not be repeated.

The image sensor 300 includes an insulating portion 304 and optical waveguide PGP301, instead of the insulating portion 4 and optical waveguide PGP1.

The insulating portion 304 includes a first interlayer dielectric film 304a and second interlayer dielectric film 304b.

The first interlayer dielectric film 304a is arranged between a fourth plane PL4 and a first plane PL1. The fourth plane PL4 includes the lower face of an uppermost wiring layer 5b among a plurality of wiring layers 5. The second interlayer dielectric film 304b is arranged between a passivation film 15 and the fourth plane PL4. The ratio of the thickness of the second interlayer dielectric film 304b to that of the first interlayer dielectric film 304a is lower than the ratio in the first embodiment.

The optical waveguide PGP301 includes an upper waveguide structure 314 and air gap structure AG301, instead of the upper waveguide structure 14 and air gap structure AG1. The upper waveguide structure 314 is arranged between the passivation film 15 and the fourth plane PL4. The air gap structure AG301 is arranged between the fourth plane PL4 and the first plane PL1.

In this case, a member 316 in the air gap structure AG301 becomes narrow in order to avoid interference with a wiring layer 5a. The lower portion of the upper waveguide structure 314 also becomes narrow. However, by devising the arrangement of the wiring layer 5a, the member 316 can be widened to a certain degree. The upper waveguide structure 314 interferes with only the uppermost wiring layer 5b among the plurality of wiring layers 5. Thus, the upper waveguide structure 314 can be designed more freely than in a case (first embodiment) wherein it interferes with the uppermost wiring layer 5b and lower wiring layer 5a among the plurality of wiring layers 5.

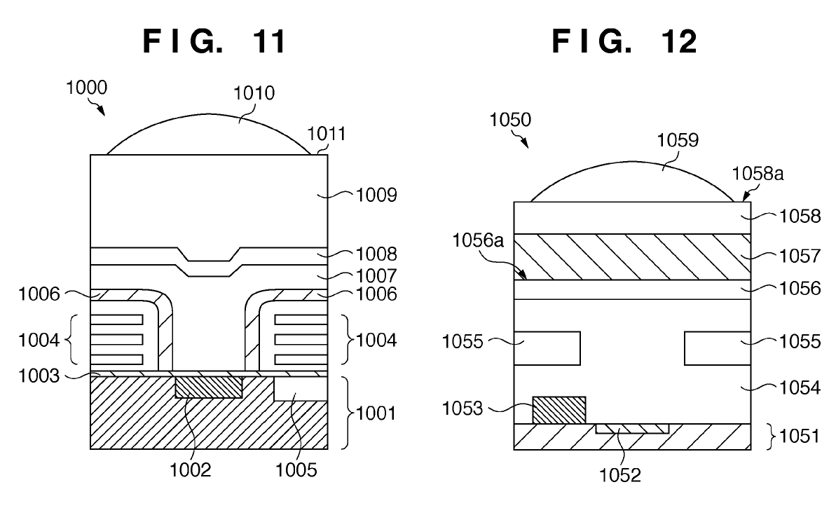

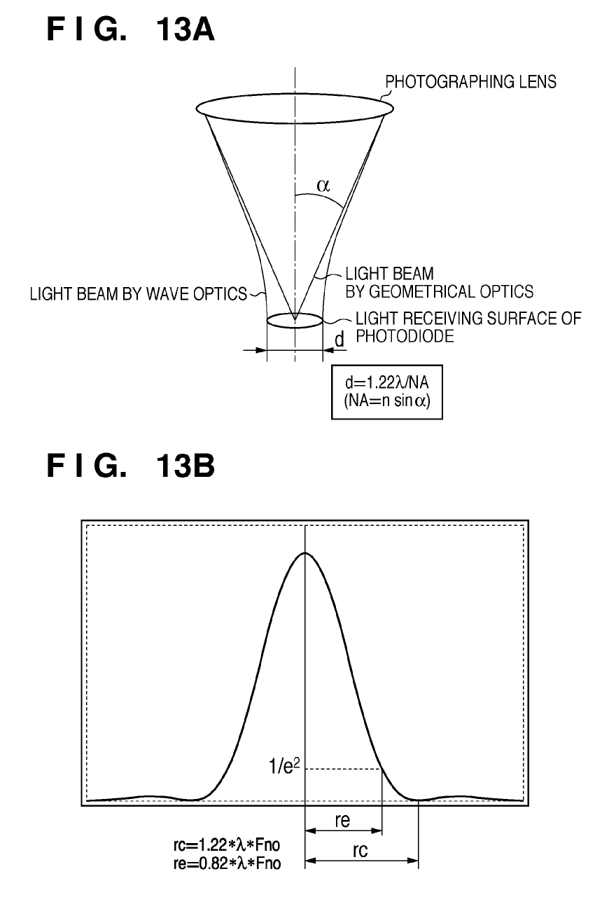

The sectional structure of an image sensor 400 according to the fourth embodiment of the present invention will be explained with reference to FIG. 10. FIG. 10 is a sectional view showing the sectional structure of the image sensor 400 according to the fourth embodiment of the present invention. A difference from the first embodiment will be mainly explained, and a description of the same part will not be repeated.

The image sensor 400 includes an optical waveguide PGP401, instead of the optical waveguide PGP1.

The optical waveguide PGP401 includes an air gap structure AG401, instead of the air gap structure AG1. In the air gap structure AG401, a gap 411 is positioned below a lowermost wiring layer 5a among a plurality of wiring layers 5. In other words, the gap 411 is positioned not on the outer region 2a2 (see FIG. 3) but on the peripheral region 11a. Thus, a member 416 becomes wider than that in the first embodiment. For example, the lower face of the member 416 can be equivalent to the light receiving surface 2a.

This structure can be formed as long as interference between the through-hole plug (e.g. a through-hole plug connecting the wiring layer 5a and a semiconductor region in the semiconductor substrate 1) and the wiring layers 5 is avoided. This structure can widen the lower portion of an upper waveguide structure 414. At this time, a light receiving surface 2a of a photoelectric conversion unit 2 may also be designed wide in accordance with the width of the member 416 in the air gap structure AG401 so as to be able to photoelectrically convert a wide light beam. Since the width of the member 416 in the air gap structure AG401 can be set relatively large (e.g., an average width of 0.25 μm), the optical waveguide function of the air gap can also be improved.

In the above-described embodiments, the microlens is arranged above the photoelectric conversion unit. It is also possible to make the layer on the planarized film 8 flat without giving any power of lens, and direct light having passed through the flat layer to the photoelectric conversion unit.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2008-098746, filed Apr. 4, 2008 which is hereby incorporated by reference herein in its entirety.

What is claimed is:

1. An image sensor comprising:
a photoelectric conversion unit; and
an optical waveguide which directs light to the photoelectric conversion unit,
the optical waveguide including
an upper waveguide structure in which a substance higher in refractive index than a first insulating portion is surrounded on a side face by the first insulating portion so as to make the light travel toward the photoelectric conversion unit, and
a gap structure in which a member is arranged between the photoelectric conversion unit and the upper waveguide structure, and a gap is formed between the member and a second insulating portion.

2. The sensor according to claim 1, wherein
the member is formed of the same substance as a substance of the second insulating portion.

3. The sensor according to claim 1, further comprising:
a microlens arranged above the photoelectric conversion unit; and
a plurality of wiring layers arranged between the photoelectric conversion unit and the microlens,
wherein the gap structure is arranged between a first plane including a light receiving surface of the photoelectric conversion unit and a second plane including a lower face of a lowermost wiring layer among the plurality of wiring layers.

4. The sensor according to claim 1, wherein
the optical waveguide further includes an antireflection film arranged between the upper waveguide structure and the gap structure.

5. The sensor according to claim 1, wherein
an upper portion of the upper waveguide structure is wider than a lower portion of the upper waveguide structure.

6. The sensor according to claim 5, wherein
the upper waveguide structure has a side face which obliquely extends from an edge portion of an upper face to an edge portion of a lower face to come close to a normal passing through a center of the light receiving surface of the photoelectric conversion unit.

7. An image sensor comprising:
a photoelectric conversion unit; and
an optical waveguide which directs light to the photoelectric conversion unit,
the optical waveguide including
an upper waveguide structure in which a substance higher in refractive index than a first insulating portion is surrounded on a side face by the first insulating portion so as to make the light travel toward the photoelectric conversion unit, and
a gap structure which is obtained by etching an insulating layer to be arranged between the photoelectric conversion unit and the upper waveguide structure so as to expose not an inner region but an outer region on a light receiving surface of the photoelectric conversion unit, and in which a gap is formed between a member serving as a portion on the inner region in the insulating layer and a second insulating portion serving as a peripheral portion on the periphery of the outer region in the insulating layer.

8. A method of manufacturing an image sensor having a photoelectric conversion unit, the method including:
a first step of forming a first insulating layer so as to cover the photoelectric conversion unit;
a second step of etching the first insulating layer so as to expose not the inner region but the outer region on a light receiving surface of the photoelectric conversion unit and thereby forming a gap structure in which a gap is formed between a member serving as a portion on the inner region in the first insulating layer, and a first insulating film serving as a peripheral portion on the periphery of the outer region in the first insulating layer;
a third step of forming an antireflection film on the gap structure;
a fourth step of forming a second insulating layer on the antireflection film;
a fifth step of forming an opening in the second insulating layer at a position above the gap structure and thereby forming a second insulating film;
a sixth step of burying a substance higher in refractive index than the second insulating film in the opening and thereby forming an upper waveguide structure; and
a seventh step of forming a microlens above the upper waveguide structure,
wherein the upper waveguide structure, the antireflection film, and the gap structure function as an optical waveguide which directs light having passed through the microlens to the photoelectric conversion unit.

9. The method according to claim 8, wherein,
in the fifth step, the antireflection film functions as an etching stopper when etching the second insulating layer so as to form the opening.
